(19) United States
(12) Patent Application Publication
(10) Pub. No.: US 2012/0229226 A1
(43) Pub. Date: Sep. 13, 2012

(54) Micromechanical Resonator

(75) Inventors: Aarne Oja, Espoo (FI); Tuomas Pensala, Espoo (FI); Johanna Meltaus, Espoo (FI)

(73) Assignee: TEKNOLOGIAN TUTKIMUSKESKUS VTT, Espoo (FI)

(21) Appl. No.: 13/497,805

(22) PCT Filed: Sep. 27, 2010
(86) PCT No.: PCT/FI2010/050744

§ 371 Date: May 30, 2012

(30) Foreign Application Priority Data
Sep. 28, 2009 (FI) 20095988

(51) Int. Cl. H03B 5/32

(52) U.S. Cl. 331/158

(57) ABSTRACT

The invention relates to a micromechanical resonator comprising a substrate (1) of first material (2), a resonator (3) suspended to the supporting structure (1), the resonator (3) being at least partially of the same material (2) as the supporting structure and dimensioned for resonation at a specific frequency f₀, coupling means (5) for initiating, maintaining and coupling the resonation of the resonator (3) to an external circuit (6), and the resonator (3) including second material (4), the thermal properties of which being different from the first material (2). In accordance with the invention the resonator (3) includes the second material (4) located concentrated in specific places of the resonator (3).

The invention relates to a micromechanical resonator in according to the preamble of claim 1.

Thermal drift remains as the main obstacle in the way of Silicon MEMS resonators entering the market of quartz crystal oscillators. Compensation of the drift can be done by replacing part of the resonating volume with material showing opposite sign of thermal drift of resonance frequency than Silicon, such as amorphous SiO₂. Resonator performance is then compromised as compared to purely single crystal resonator.

Conventionally, problems relating to temperature drift of micromechanical resonators have been solved by using a temperature compensating surrounding structure (typically SiO₂) around the basic silicon material or alternatively by using SiO₂ as a part of the structure distributed essentially uniformly in the complete structure. This technology is described in more detail e.g., in publication “Temperature compensation in silicon-based microelectromechanical resonators”, F. Schoen et al (ISBN: 978-1-4244-2978-3/09),

It is an object of the present invention to overcome at least some of the disadvantages of the above-described techniques and to provide an entirely novel type micromechanical resonator and a method for manufacturing a micromechanical resonator.

The goal of the invention is achieved by virtue of locating the thermally compensating second material concentrated in specific places of the resonator.

In one preferred embodiment of the invention a passive compensation of the thermal drift of resonance frequency is used with an optimised way by using the compensating material concentrated in the stress maximum(s) of the resonator. When realised, the commercial significance is vast by providing a method to fabricate MEMS resonators that can potentially compete with the traditional quartz resonator technology. This invention states how to minimize the amount of compensating material by placing it where it is most effective—that is—in the stress maximum (displacement node).

Another preferred embodiment of the invention is based on the use of SiO₂ or TeO₂ in the middle of the vibrating structure.

A further preferred embodiment of the invention is based on dimensioning the parts of the second material of the resonator laterally larger than 10 μm.

More specifically, the micromechanical resonator according to the invention is characterized by what is stated in the characterizing part of claim 1.

The invention provides significant benefits.

Replacing a fraction of the resonating volume with material with opposite sign thermal drift of resonance frequency reduces the thermal drift. The fraction needed for a given level of reduction is at its smallest when the compensating material is placed at the stress maximum position for the resonance mode being used. Considering a beam vibrating in length extensional mode, placing small amount of compensating material at the ends of the beam i.e. at the stress minimums/displacement maximums, will have a very small effect as the compensating material acts mostly as a passive mass load only, whereas the rest of the beam material acts as spring. If, instead, the compensating material is placed in the middle of the beam, the compensating material acts mainly as the spring having high stress and strain within itself, and compensates the thermal drift more effectively.

Some of the structure embodiments described in this application (such as the fully oxidized spring area) have the important advantage that fabrication tolerances of both the resonant frequency and of thermal coefficient of the resonance frequency are reduced. Fabrication tolerances affect device testing and tuning needs and affect significantly the cost of resonators. In a resonator with a fully oxidized spring area, there is only one interface, the circumference of the laterally relatively large oxide area in the middle of the resonator, whose exact location affects fabrication tolerances.

Materials-based thermal compensation method have several advantages over various active electrical compensation schemes: there is no power consumption, they do not suffer from slowness of the servo system, nor is the spectral purity deteriorated.

In the following, the invention will be examined in greater detail with the help of exemplifying embodiments illustrated in the appended drawings, in which

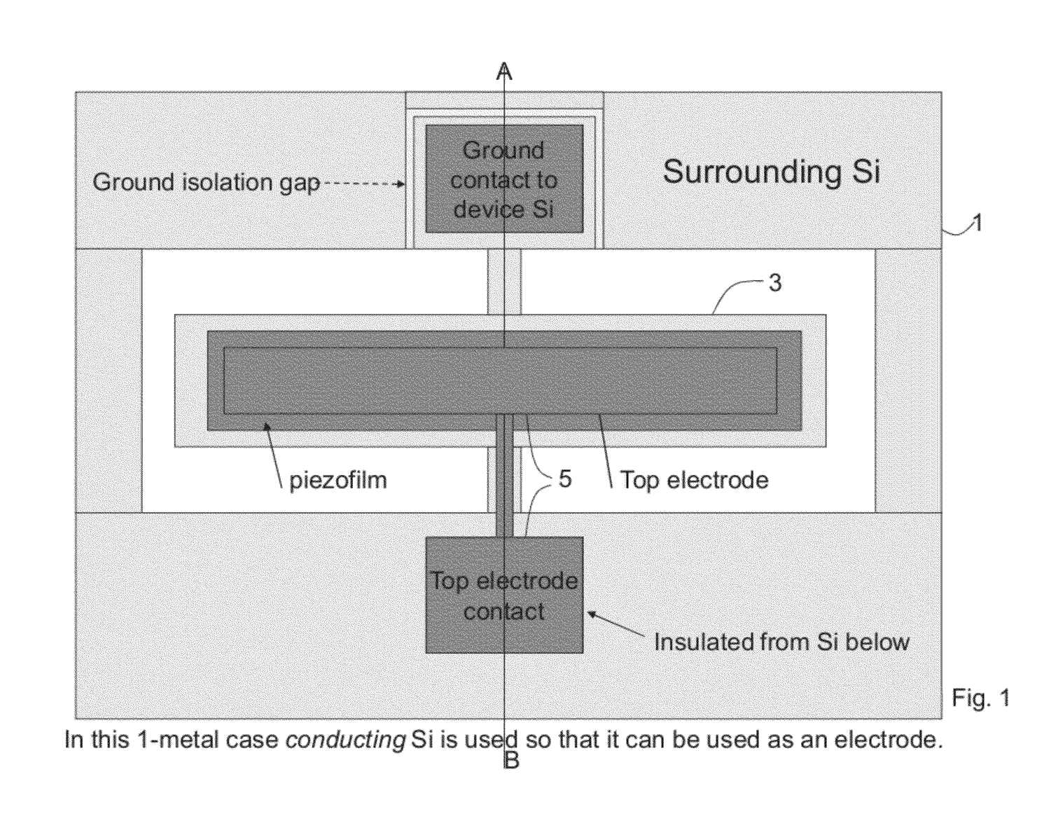

FIG. 1 shows a top view of a resonator applicable with the invention using a piezofilm as a part of the component.

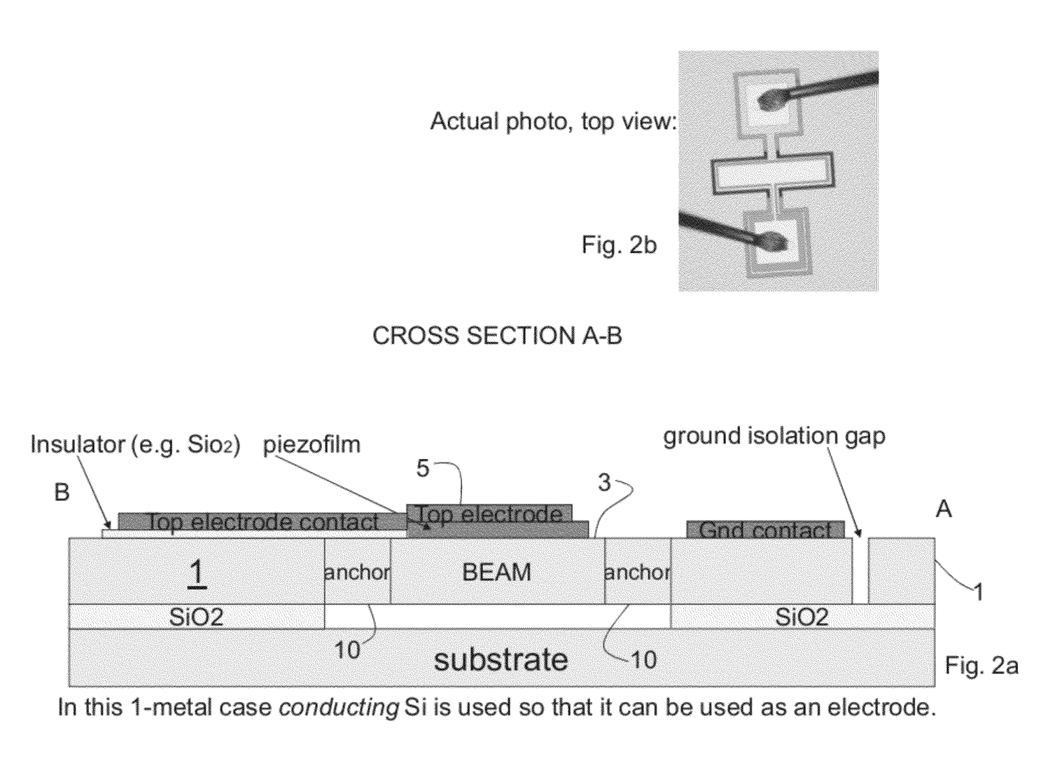

FIG. 2a shows as a side view the resonator of FIG. 1.

FIG. 2b shows as a top view a photograph of an actual component of the resonator of FIG. 1.

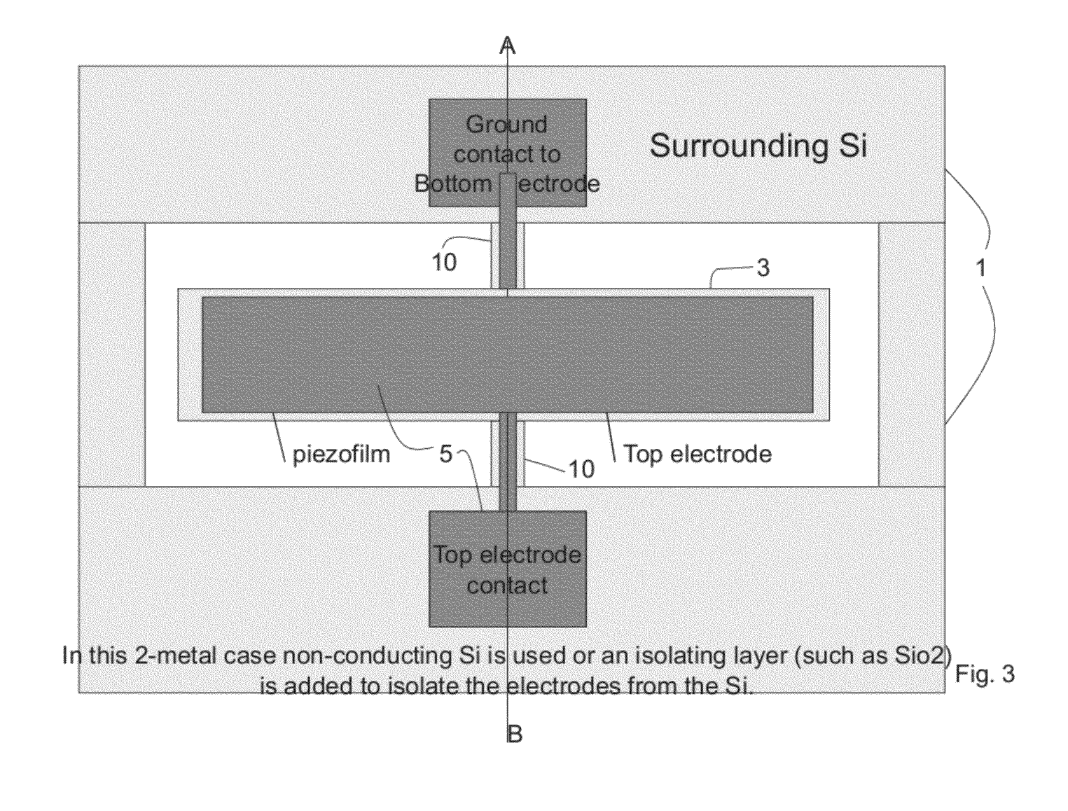

FIG. 3 shows a top view of another resonator applicable with the invention using a piezofilm as a part of the component.

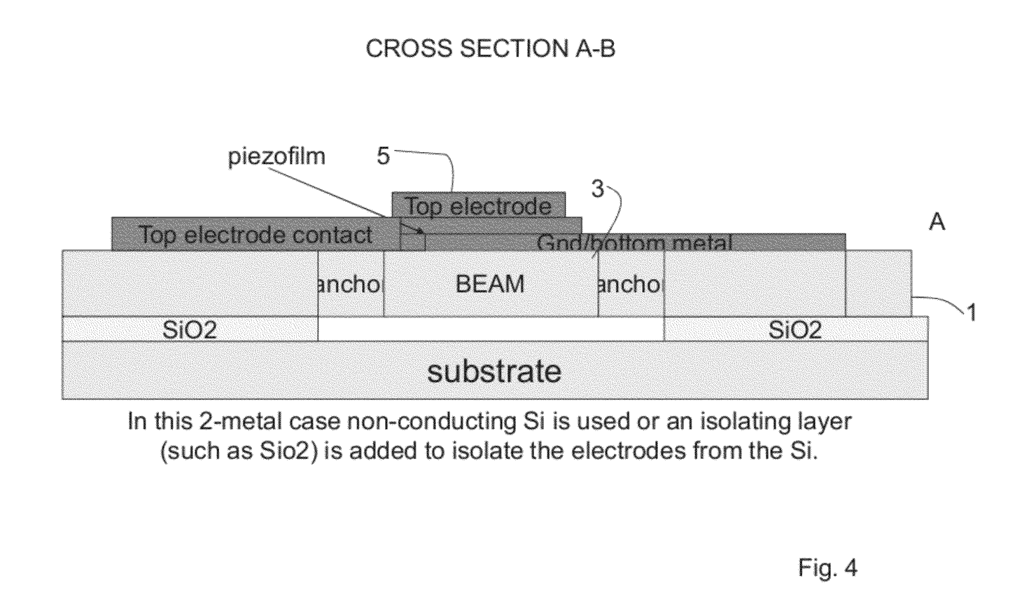

FIG. 4 shows as a side view the resonator of FIG. 3.

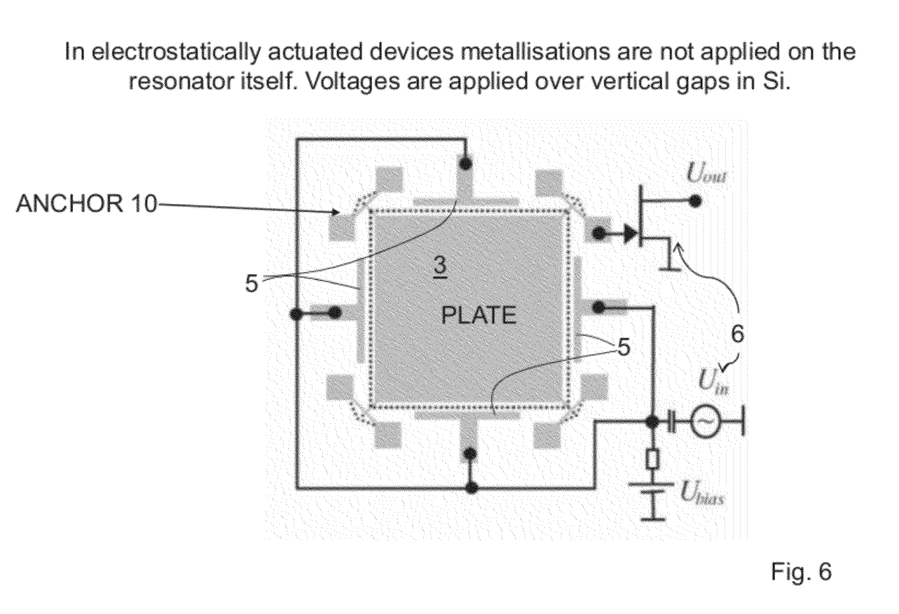

FIG. 6 shows as a schematic top view an electrostatically actuated plate resonator applicable with the invention.

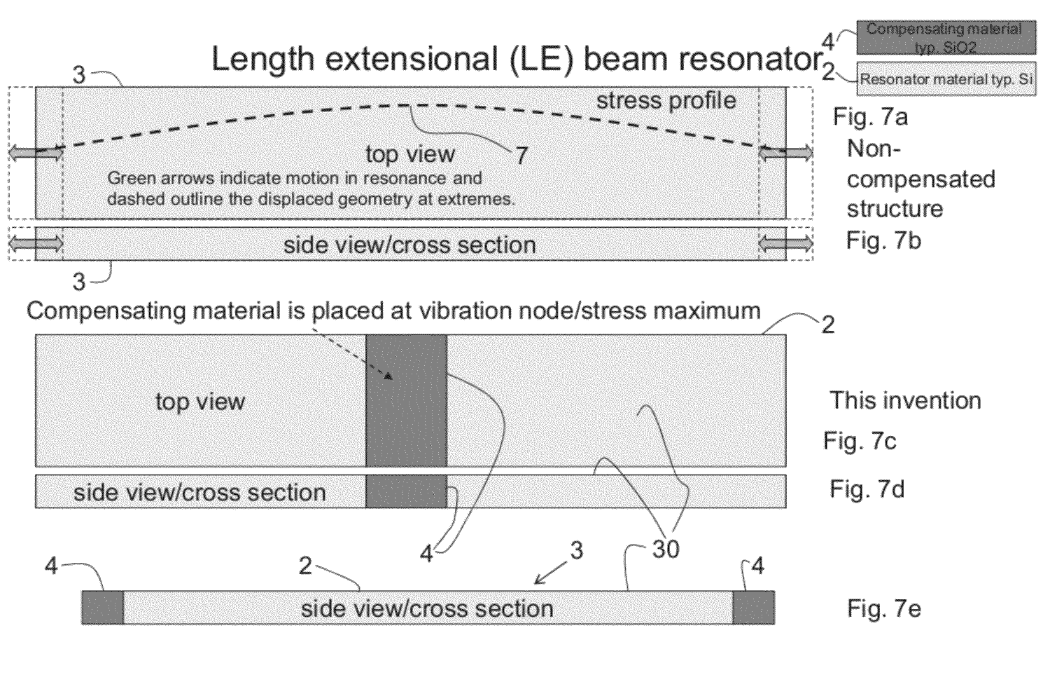

FIG. 7a shows as a schematic top view a length extensional (LE) beam resonator applicable with the invention.

FIG. 7b shows as a schematic side view the length extensional (LE) beam resonator of FIG. 7a.

FIG. 7c shows as a schematic top view a length extensional (LE) beam resonator in accordance with the invention.

FIG. 7d shows as a schematic side view the length extensional (LE) beam resonator of FIG. 7c.

FIG. 7e shows as a schematic side view the length extensional (LE) beam resonator in accordance with one alternative solution of the invention.

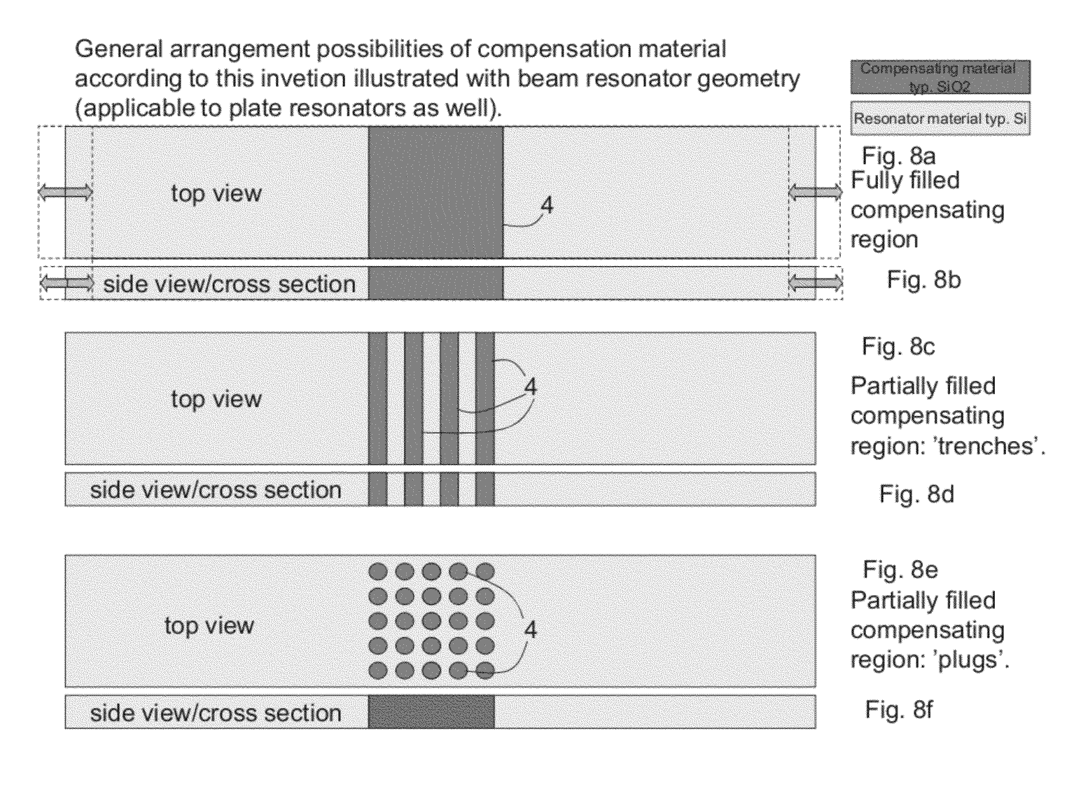

FIG. 8a shows as a schematic top view a length extensional (LE) beam resonator with a fully filled compensating region in accordance with the invention.

FIG. 8b shows as a schematic side view the length extensional (LE) beam resonator of FIG. 8a.

FIG. 8c shows as a schematic top view a length extensional (LE) beam resonator with a partially filled compensating region (trenches) in accordance with the invention.

FIG. 8d shows as a schematic side view the length extensional (LE) beam resonator of FIG. 8c.

FIG. 8e shows as a schematic top view a length extensional (LE) beam resonator with a partially filled compensating region (plugs) in accordance with the invention.

FIG. 8f shows as a schematic side view the length extensional (LE) beam resonator of FIG. 8e.

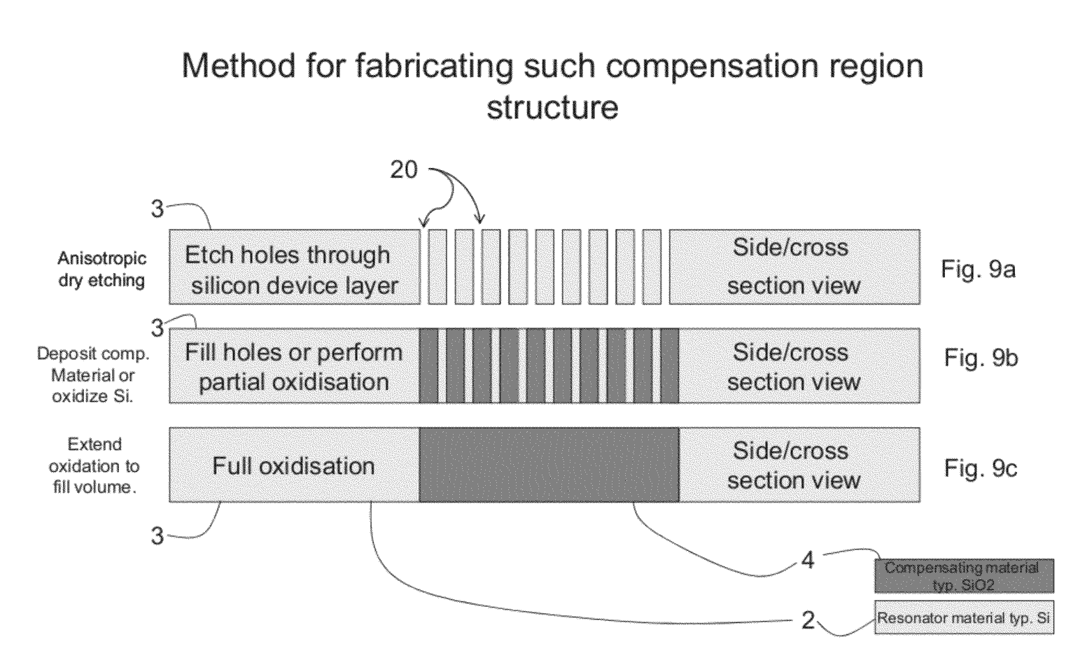

FIGS. 9a-9c show schematically a possible method for fabricating a compensation region structure in accordance with the invention.

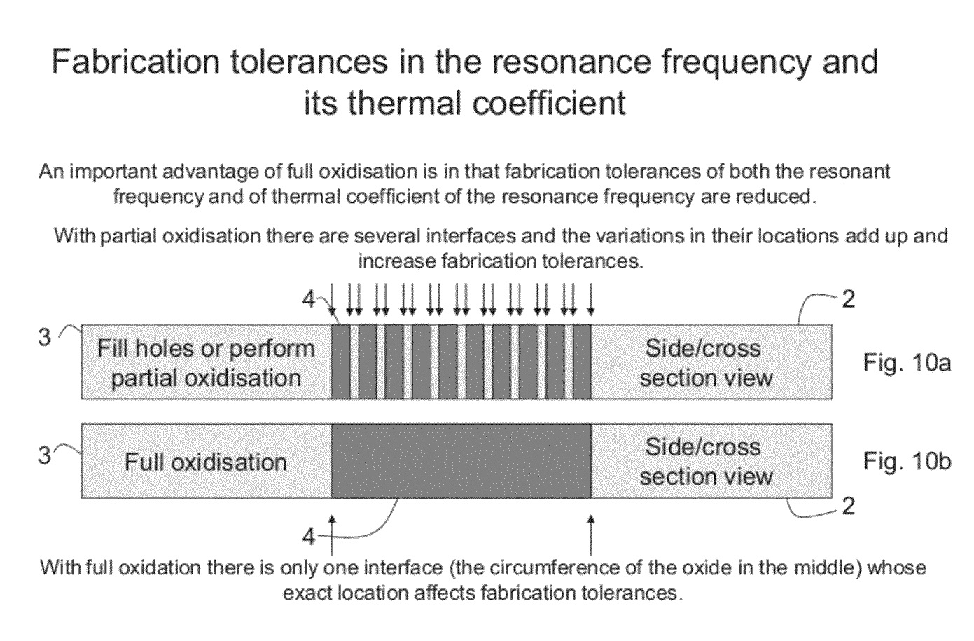

FIGS. 10a-10b show schematically another possible method for fabricating a compensation region structure in accordance with the invention.

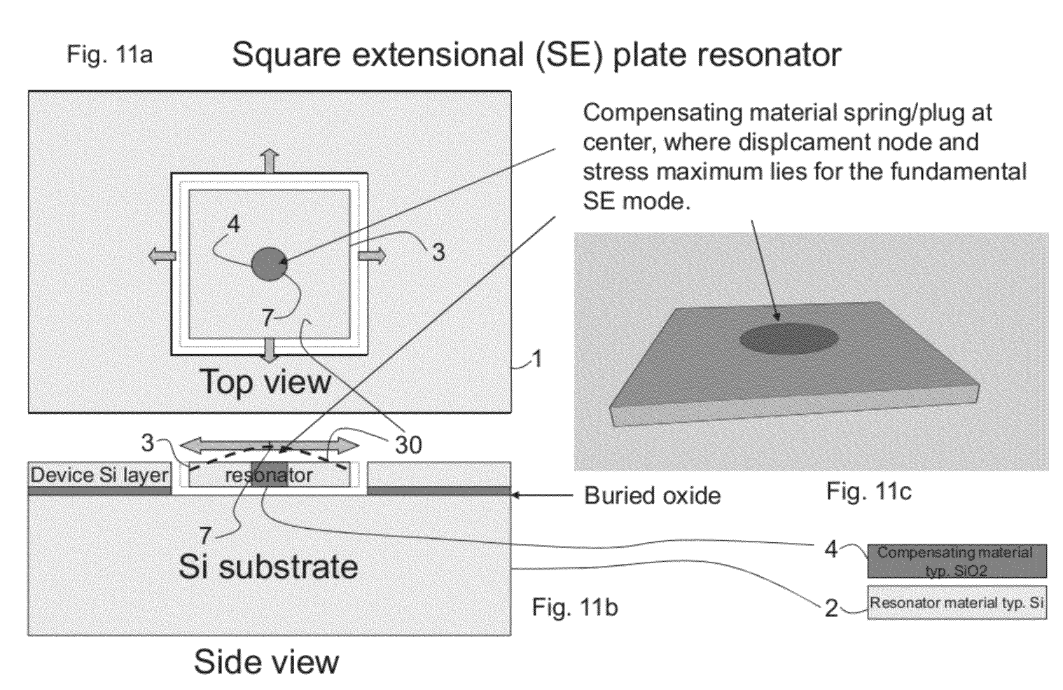

FIG. 11a shows as a schematic top view a square extensional (SE) plate resonator with a fully filled compensating region (trenches) in accordance with the invention.

FIG. 11b shows as a schematic side view the resonator of FIG. 11a.

FIG. 11c shows as a perspective view the resonator element of FIG. 11a.

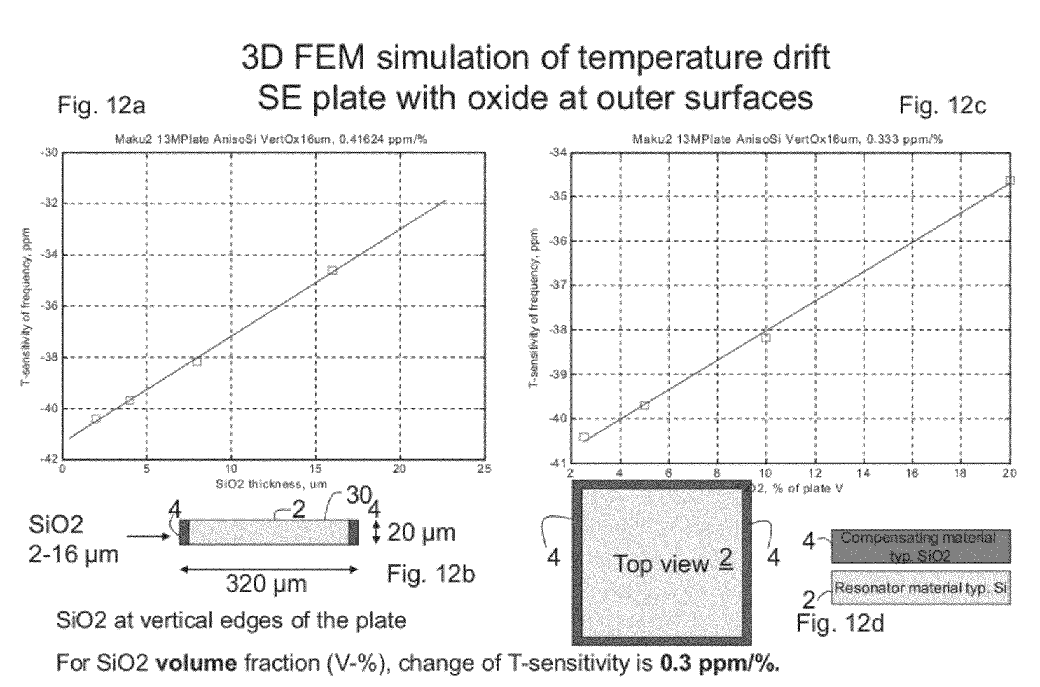

FIGS. 12a-12d show graphically the influence of the compensating region when positioned at the edges of the resonator.

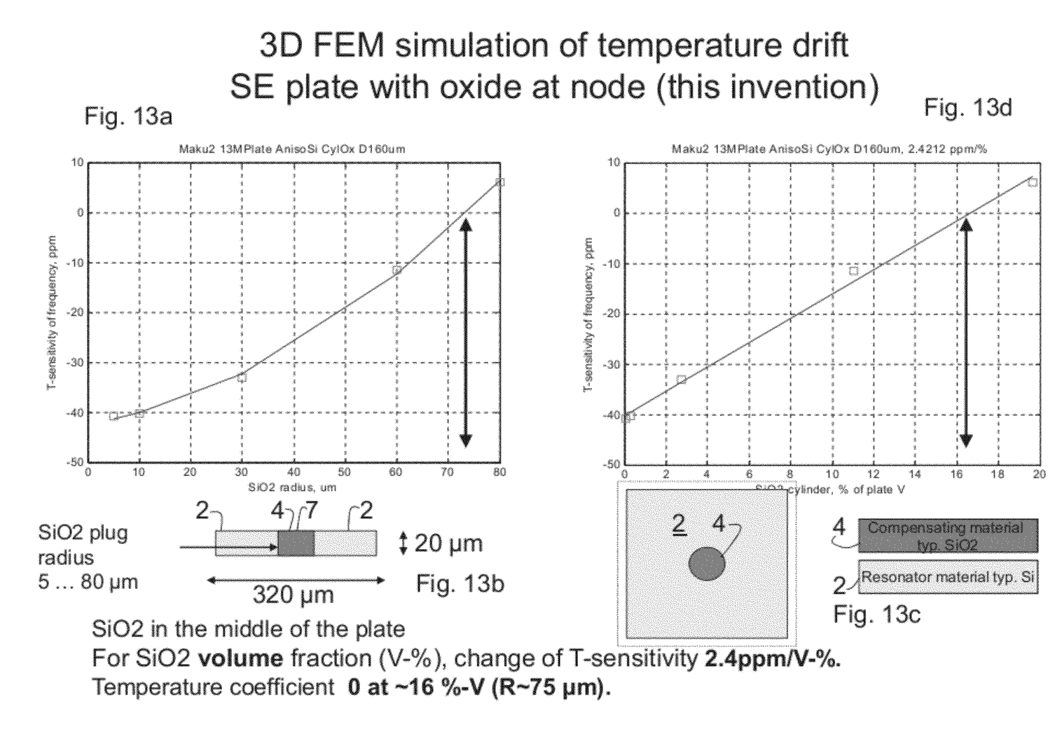

FIGS. 13a-13d show graphically the influence of the compensating region when positioned at the stress maximum the resonator in accordance with the invention

FIG. 4a shows as a schematic top view a vertical BAW SOI resonator with a fully filled compensating region in accordance with the invention.

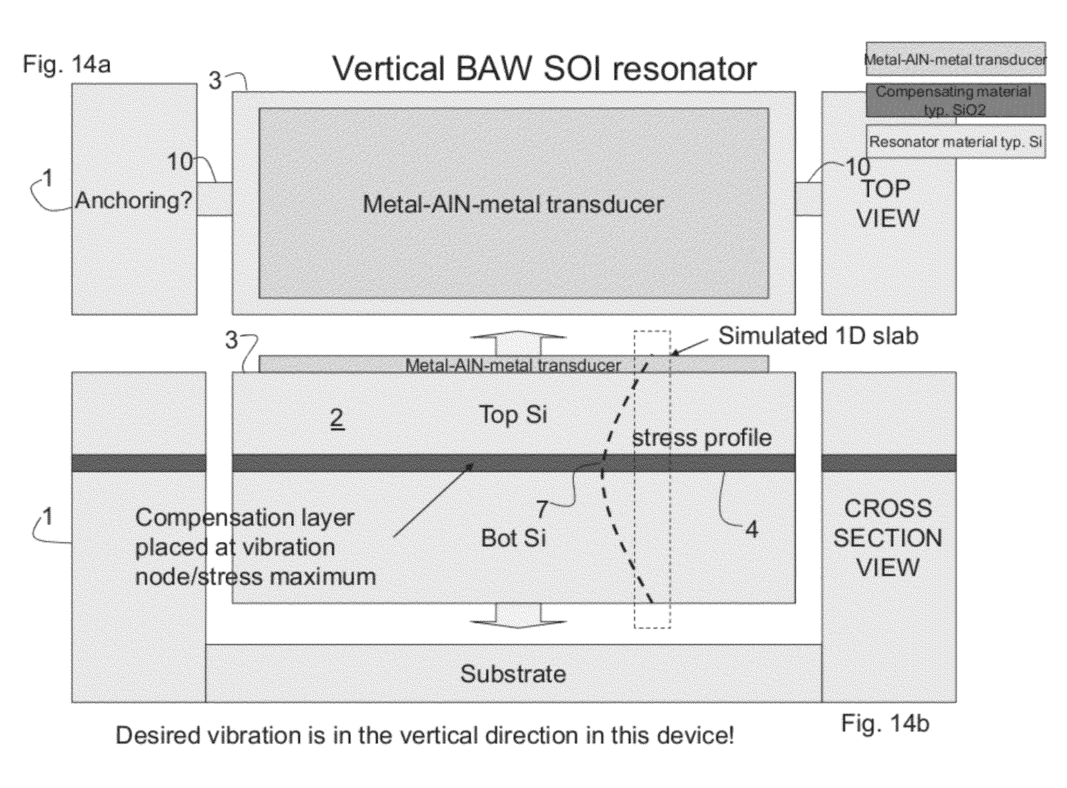

FIG. 14b shows as a schematic side view the resonator of FIG. 8a.

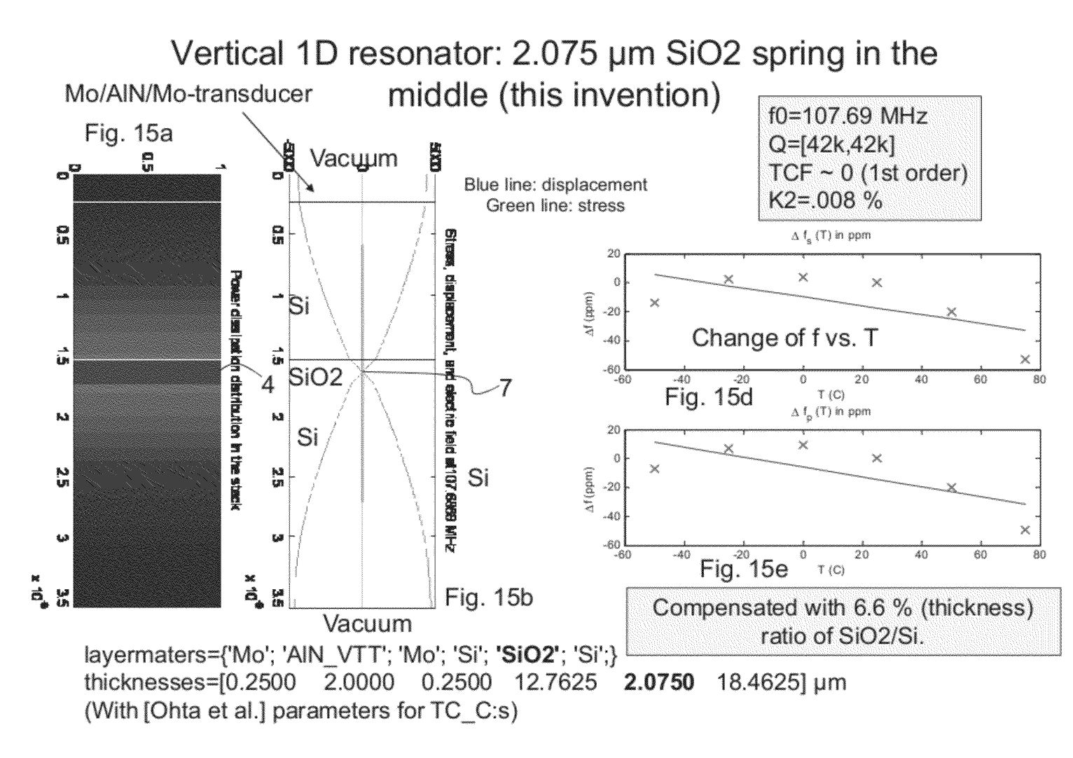

FIGS. 15a-15e show graphically the influence of the compensating region in a vertical 1D resonator having a 2.075 μm SiO₂ spring in the middle at the stress maximum the resonator in accordance with the invention.

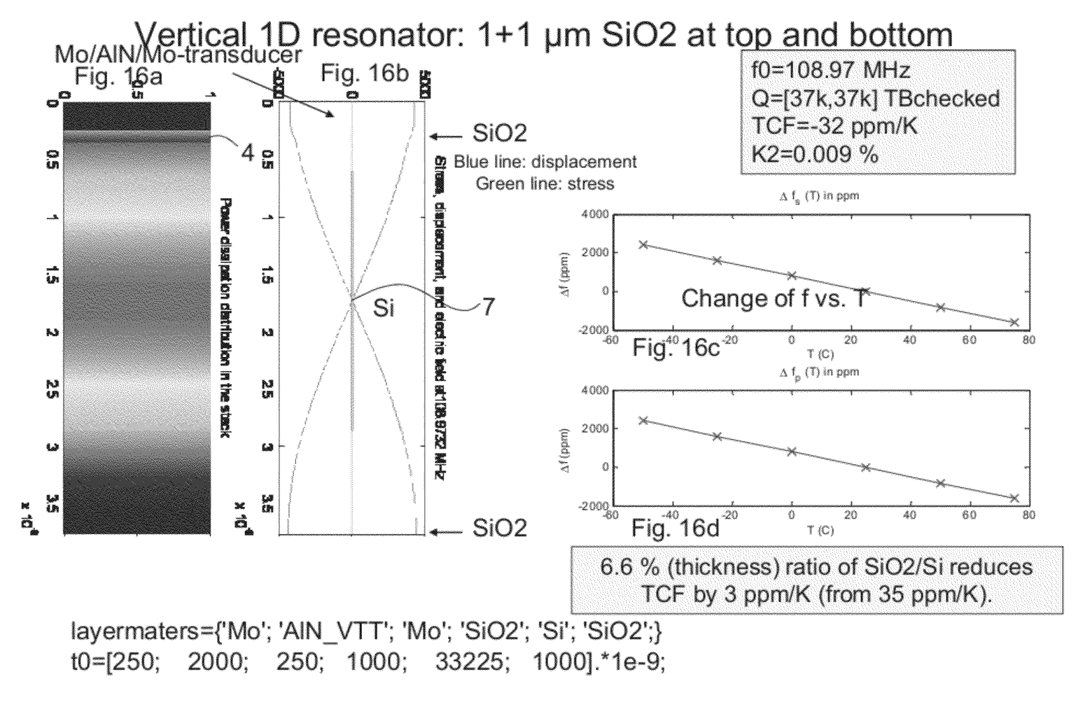

FIGS. 16a-16d show graphically the influence of the compensating region in a vertical 1D resonator having a SiO₂ layers at top and bottom of the resonator.

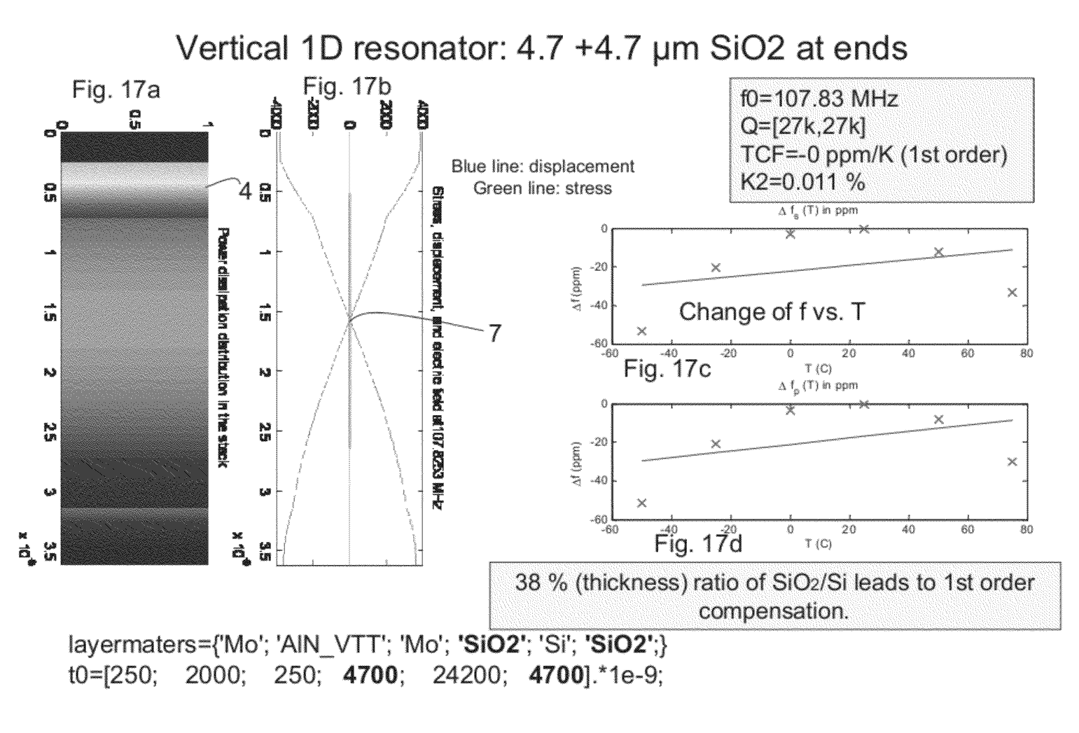

FIGS. 17a-17d show graphically the influence of the compensating region in a vertical 1D resonator having a um SiO₂ layers at ends of the resonator.

In accordance with FIGS. 1-4 the present invention is related to micromechanical structures, where a resonator 3 is suspended to a supporting structure 1 by anchors 10. The supporting structure 1 is in one typical embodiment of the invention a silicon device layer of a SOI (Silicon On Insulator) wafer. The dimensions and the suspension of the resonator 3 are such that it vibrates with a specific frequency f₀ when excited by a corresponding electrical signal. A typical length of a beam resonator is 320 μm and height 20 μm. The excitation can be made capacitively by electrodes 5 formed on resonator 3 and on substrate 1 or alternatively by piezoelectric structures of FIG. 2a or 4.

The electrical signal can be conducted to the structures by electrodes or by making the complete structure conductive to the electrical signal. Typical materials in a resonator are Si for conductive structures and amorphous SiO₂ for isolators. Amorphous Te O₂ is also an alternative material for isolation. Also a SOI (Silicon On Insulator) wafer may be used as a preform for the resonator.

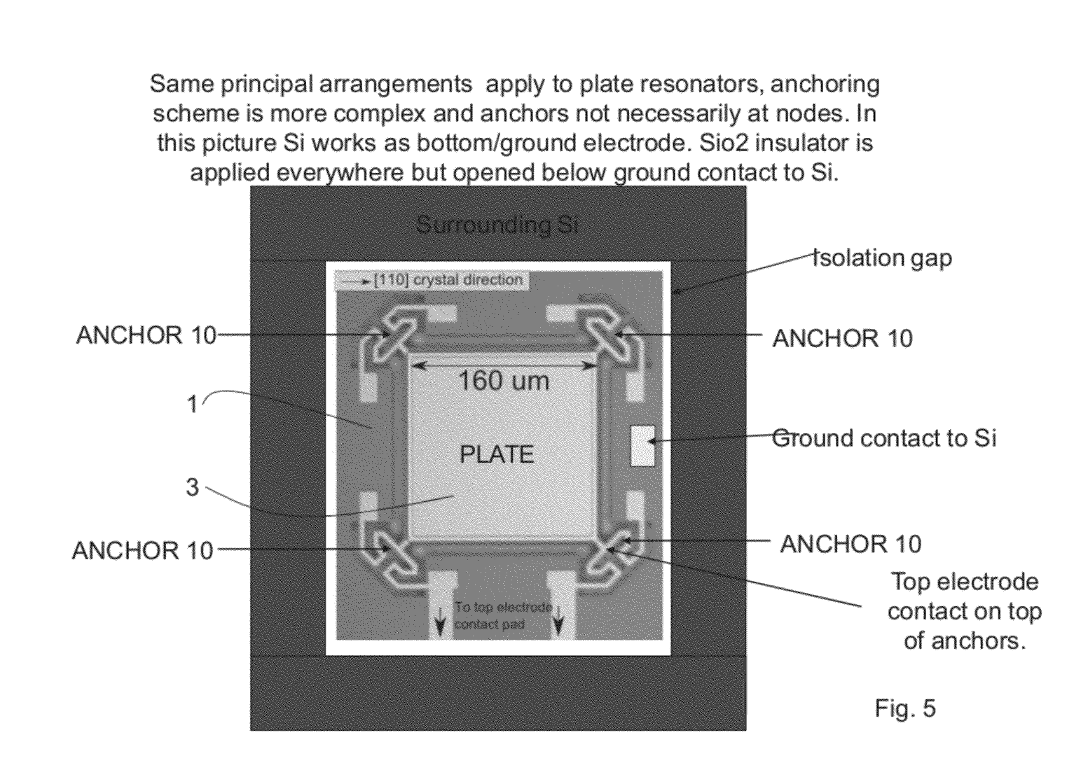

FIG. 5 shows a plate resonator. Same principal arrangements apply to plate resonators, anchoring scheme is more complex and anchors not necessarily at nodes. In this picture Si works as bottom/ground electrode. Sio₂ insulator is applied everywhere but opened below ground contact to Si.

FIG. 6 shows an electrostatically actuated device, where metallization are not applied on the resonator itself. Voltages are applied over vertical gaps in Si. An external electrical circuit 6 takes care of the excitation and maintenance of the resonance.

FIGS. 7a and 7b show the resonator element 3 in more detail and also a stress profile for the resonator is presented with a maximum 7 in the middle of the beam 3.

In FIGS. 7a and 7b is presented the basic solution of the invention where a region of temperature compensating material 4, e.g., SiO₂ or TeO₂ (Tellurium oxide) is positioned at the stress maximum of beam 3. The width of the area 4 is about 10% of the length of the beam 3, but depending of the basic material and geometry of the beam it may vary in the range of 5-30%. Instead of SiO₂ or TeO₂, a glass material with similar thermal properties may be used.

In accordance with FIG. 7e the second material 4 may be placed at the ends of the resonator 3. In one advantageous solution of the invention the areas of second material are laterally dimensioned to be larger than 10 μm. Lateral dimension here means the dimension in the plane of the upper surface 30 of the resonator 3. This upper surface 30 of the resonator 3 is e.g. the surface visible in FIG. 7c or alternatively in FIGS. 11a and 11b. By this dimensioning the problems with production tolerances may be minimized This way dimensioning is applicable also for solutions of FIGS. 7a and 7b if the other dimensioning rules, e.g., for f₀ are met.

FIGS. 8a and 8b correspond to solution of FIGS. 7a-7d. FIGS. 8c-8d show a partially filled compensating region 4 formed by transverse trenches.

In FIGS. 9a-9c is described in more detail a process for manufacturing the resonator. In accordance with FIG. 9a holes 20 are etched through silicon device layer (e.g., anisotropic dry etching). This is a standard etching process known by the man skilled in the art. In FIG. 9b holes are filled by a deposition phase or alternatively a partial oxidization is made. In stage of FIG. 9c oxidation is extended to fill the complete volume.

In other words the typical embodiments of the invention are:

1) Creating an oxide or partially oxide (or other compensating material) region 4 through the depth of resonator device layer 4 in the middle of a square extensional resonator 3.

2) Creating an oxide or region of partially oxide (or other compensating material) 4 in the middle of a length extensional beam resonator 3.

3) Creating similarly compensation regions for other resonator geometries and resonant modes by placing the compensation material in the stress maximum/displacement node positions.

4) Placing compensating layer 4 in a vertically stacked thin-film-silicon-on-insulator resonator similarly in the stress maximum instead of extreme surfaces. Illustrations of the embodiments and associated simulation results have been described above with the figures.

This invention has focused on finding thermally compensated resonator structures which minimize the amount of oxide material by placing the oxide in a position with the largest effect on the thermal coefficient. Simulations on 1-D length-extensional resonators show that by placing the oxide at the end of the extending bars one needs as much as 38% volume ratio of the oxide. (The actual number is of course sensitive to the materials parameters which do have some uncertainty.) It should be noted that also this solution is a good solution if the large amount of oxide does not have any significant adverse effects. Assuming again the oxide area is “fully oxidized” (see the discussion above), the fabrication tolerances in the exact location of the oxide-silicon interface, do not have a large effect on the value of the resonance frequency of the value of the thermal coefficient. From the lithography point of view, it is in fact advantageous that the volumes of the silicon and the oxide would be as equal as possible. What differentiates such a structure from previously described solutions is again that the oxide forms one large volume (with all dimensions much larger than 1 micrometer).

In this application the resonator 3 means the actual mechanically vibrating element and by the supporting structure 1 is meant the construction to which the resonator is suspended to.

The second material 4, also called here compensating material 4, has different thermal properties than the first material 2 of the supporting structure 1. In the preferred embodiment of the invention the thermal dependence of the sound velocity in the material is opposite to each other in these two structures. This condition is met for example to the following pairs:

First material: Si

Second material: amorphous SiO₂ or amorphous TeO₂ or glass with suitable thermal properites.

For the man skilled in the art it is clear that a resonator may have several tension maximums at the specific frequency f₀, and then the method will be applied to all of them.

1. Micromechanical resonator comprising:
a supporting structure of first material,
a resonator suspended to the supporting structure, the resonator being at least partially of the same material as the supporting structure and dimensioned for resonation at a specific frequency f₀,
coupling means for initiating, maintaining and coupling the resonation of the resonator to an external circuit,
wherein the resonator includes a second material, the thermal properties of which being different from the first material,
wherein the second material of the resonator is located concentrated in specific places of the resonator, and
wherein the parts of the resonator of the second material are dimensioned laterally larger than 10 μm.

2. A resonator in accordance with claim 1, wherein the parts of the resonator of the second material are at least mainly in an area(s) where the resonator has a tension maximum(s) at the specific frequency f₀.

3. A resonator in accordance with claim 1, wherein the parts of the resonator of the second material are at least mainly at the lateral ends of the resonator.

4. A resonator in accordance with claim 1, wherein the first material is silicon and the second material is silicon oxide, Tellurium oxide or glass.

5. A resonator in accordance with claim 1, wherein the resonator is a beam suspended in the middle of the structure to the substrate.

6. A resonator in accordance with claim 1, wherein the resonator is a plate suspended to the substrate from the corners of the plate.

7. A resonator in accordance with claim 1, wherein the parts of the second material are uniform.

8. A resonator in accordance with claim 1, wherein the parts of the second material placed to the stress maximum are only partially filling the first material as trenches or plugs.

9. A resonator in accordance with claim 1, wherein the resonator is a length extensional beam resonator.

10. A resonator in accordance with claim 1, wherein the resonator is a square extensional plate resonator.

11. A resonator in accordance with claim 1, wherein the resonator is a vertical Bulk Acoustic Wave SOI resonator.

12. A resonator in accordance claim 1, wherein the thermal dependence of the sound velocity of the first material is opposite to the second material.
